(19) United States
(12) Patent Application Publication
(10) Pub. No.: US 2026/0297264 A1
(43) Pub. Date: Oct. 1, 2026

(54) MALEIMIDE RESIN, RESIN COMPOSITION, CURED PRODUCT, SHEET, LAMINATE, AND PRINTED WIRING BOARD

(71) Applicant: Resonac Corporation, Minato-ku, Tokyo (JP)

(72) Inventors: Kitaru SATO, Tokyo (JP); Tetsuya IMAI, Tokyo (JP); Yusuke BABA, Tokyo (JP)

(21) Appl. No.: 19/479,715

(22) PCT Filed: Nov. 1, 2024
(86) PCT No.: PCT/JP2024/039127

§ 371 Date: Oct. 28, 2025

(30) Foreign Application Priority Data
Nov. 6, 2023 (JP) 2023-189505

(51) Int. Cl. C08G 73/12; B05D 3/04; B05D 7/14; C08K 5/14; C08L 79/08

(52) U.S. Cl. CPC C08G 73/127; B05D 3/0473; B05D 7/14; C08K 5/14; C08L 79/085; B05D 2202/45; B05D 2401/10; B05D 2505/50; C08L 2203/20

(57) ABSTRACT

A maleimide resin according to the present disclosure is a maleimide resin obtained by reacting a tetracarboxylic acid dianhydride (a1), an amine (a2), and maleic anhydride (a3), in which the tetracarboxylic acid dianhydride (a1) includes a tetracarboxylic acid dianhydride having a fluorene skeleton, and the amine (a2) include a dimer diamine and an amine having a biphenyl skeleton.

### TECHNICAL FIELD

The present disclosure relates to a maleimide resin, a resin composition, a cured product, a sheet, a laminate, and a printed wiring board.

### BACKGROUND ART

Printed wiring boards and multilayer wiring boards that use the printed wiring boards are used in products, including mobile communication devices such as mobile phones and smartphones, their base station equipment, network-related electronic devices such as servers and routers, large-scale computers, and the like.

In recent years, high-frequency electrical signals are used in those products in order to transmit and process large amounts of information at high speed; however, high-frequency signals are highly susceptible to attenuation, and therefore, insulating materials having excellent dielectric characteristics are required as insulating materials used in the above-described printed wiring boards, multilayer wiring boards, and the like in order to suppress transmission loss.

As the above-described insulating materials, the epoxy resin compositions disclosed in Patent Literatures 1 to 3 are known. Patent Literature 1 discloses that an epoxy resin composition containing an epoxy resin, an active ester compound, and a triazine-containing cresol novolac resin is effective for reducing the dielectric loss tangent. Furthermore, Patent Literatures 2 and 3 disclose that resin compositions containing an epoxy resin and an active ester compound as essential components can form cured products having a low dielectric loss tangent and are useful as insulating materials. However, it has been found that these epoxy resin compositions are not satisfactory for high-frequency band applications.

On the other hand, it is reported in Patent Literature 4 that a resin film formed from a resin composition containing a bismaleimide resin having a long-chain alkyl group as a non-epoxy-based material and a curing agent, has excellent dielectric characteristics (low relative dielectric constant and low dielectric loss tangent). However, bismaleimide resins formed only of long-chain alkyldiamines have a problem of exhibiting a low Tg and a low elastic modulus.

### CITATION LIST

### Patent Literature

Patent Literature 1: JP 2011-132507 A
Patent Literature 2: JP 2015-101626 A
Patent Literature 3: JP 2017-210527 A
Patent Literature 4: WO 2016/114287 A1

### SUMMARY OF INVENTION

### Technical Problem

It is an object of the present disclosure to provide a novel maleimide resin. It is another object of the present disclosure to provide a maleimide resin that can form a cured product which tends to have a high elastic modulus and a high Tg and has excellent toughness while sufficiently maintaining a low dielectric constant and a low dielectric loss tangent. Furthermore, it is another object of the present disclosure to provide a resin composition, a cured product, a sheet, a laminate, and a printed wiring board, all of which use the maleimide resin.

### Solution to Problem

The present disclosure provides the following maleimide resin, a resin composition, a cured product, a sheet, a laminate, and a printed wiring board.
[1] A maleimide resin obtained by reacting a tetracarboxylic acid dianhydride (a1), an amine (a2), and maleic anhydride (a3), wherein the tetracarboxylic acid dianhydride (a1) includes a tetracarboxylic acid dianhydride having a fluorene skeleton, and the amine (a2) include a dimer diamine and an amine having a biphenyl skeleton.
[2] The maleimide resin according to the above-described item [1], wherein the above-described tetracarboxylic acid dianhydride having a fluorene skeleton contains at least one of 9,9-bis(3,4-dicarboxyphenyl) fluorene dianhydride and 9,9-bis[4-(3,4-dicarboxyphenoxy)phenyl]fluorene dianhydride.
[3] The maleimide resin according to the above-described item [1] or [2], wherein the amine having a biphenyl skeleton contains at least one of 4,4′-diamino-2,2′-dimethylbiphenyl, 4,4′-diamino-2,2′=diethylbiphenyl, 4,4′-diamino-3,3′-dimethylbiphenyl, 4,4′-diamino-3,3′-diethylbiphenyl, 4,4′-diamino-3,3′,5,5′-tetramethylbiphenyl, 4,4′-diamino-3,3′,5,5′-tetraethylbiphenyl, 4,4′-diamino-2,2′-bis(trifluoromethyl) biphenyl, 4,4′-diamino-2,2′-dimethoxybiphenyl, and 4,4′-diamino-3,3′-dimethoxybiphenyl.
[4] The maleimide resin according to any one of the above-described items [1] to [3], wherein the dimer diamine contains at least one of a compound represented by the following general Formula (1), and a compound represented by the following general Formula (2):

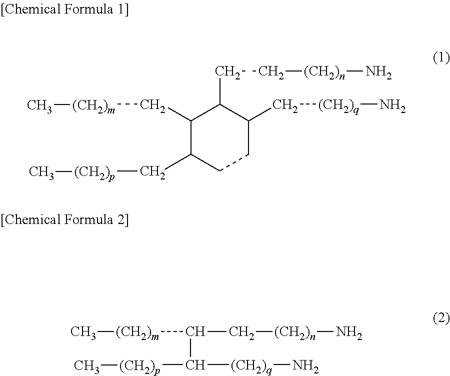

wherein in Formulas (1) and (2), m, n, p, and q each represent an integer of 1 or greater selected such that m+n=6 to 17 and p+q=8 to 19; and a bond indicated by a dashed line means a carbon-carbon single bond or a carbon-carbon double bond; provided that when the bond indicated by a dashed line is a carbon-carbon double bond, Formulas (1) and (2) have a structure in which the number of hydrogen atoms bonded to each of the carbon atoms constituting the carbon-carbon double bond is one less than the number shown in Formula (1) or (2).
[5] The maleimide resin according to any one of the above-described items [1] to [4], wherein the maleimide resin has a weight average molecular weight of 3000 to 40000.
[6] A resin composition containing the maleimide resin according to any one of the above-described items [1] to [5].
[7] The resin composition according to the above-described item [6], further containing a polymerization initiator.
[8] A cured product of the resin composition according to the above-described [6] or [7].
[9] A sheet including the resin composition according to the above-described item [6] or [7] and a substrate.
[10] The sheet according to the above-described item [9], wherein the substrate is an organic substrate.
[11] The sheet according to the above-described item [9], wherein the substrate is an inorganic substrate.
[12] A laminate obtained by further thermocompression bonding a substrate to an adhesive surface of the sheet according to any one of the above-described items [9] to [11].
[13] A printed wiring board using the sheet according to any one of the above-described items [9] to [11].
[14] A printed wiring board using the laminate according to the above-described item [12].

### Advantageous Effects of Invention

According to the present disclosure, a maleimide resin that can form a cured product which tends to have a high elastic modulus and a high Tg and has excellent toughness while sufficiently maintaining a low dielectric constant and a low dielectric loss tangent, can be provided. The present disclosure can also provide a resin composition, a cured product, a sheet, a laminate, and a printed wiring board, all of which use the maleimide resin.

The maleimide resin of the present disclosure and a resin composition (adhesive composition) that uses the maleimide resin can reduce both the dielectric constant and the dielectric loss tangent (hereinafter, both may be collectively referred to as “dielectric characteristics”) and have, in particular, excellent low dielectric characteristics in the high frequency band. Furthermore, since a cured product (adhesive layer) obtained from the above-described resin composition has a high elastic modulus and a high Tg as well as excellent toughness, the above-described resin composition is useful not only as an adhesive used in the production of printed circuit substrates (build-up substrates, flexible printed wiring boards, and the like) and copper-clad boards for printed wiring boards, but also as an insulating film for a rewiring layer and the like, a semiconductor interlayer material, a coating agent, a resist ink, a conductive paste, or the like.

### DESCRIPTION OF EMBODIMENTS

Hereinafter, a suitable embodiment of the present disclosure will be described in detail. However, the present disclosure is not limited to the following embodiments and can be carried out in various modified forms within the scope of the gist thereof.

In the present specification, a numerical value range indicated using the term “to” indicates a range including the numerical values described before and after the term “to” as the minimum value and the maximum value, respectively. With regard to a numerical value range described stepwise in the present specification, the upper limit value or lower limit value of the numerical value range of a certain stage may be arbitrarily combined with the upper limit value or lower limit value of the numerical value range of another stage. With regard to a numerical value range described in the present specification, the upper limit value or lower limit value of the numerical value range may be replaced with a value shown in the Examples. Regarding the phrase “A or B”, either A or B may be included, or both of them may be included. With regard to the materials that will be described below as examples, unless particularly stated otherwise, one kind thereof can be used alone, or two or more kinds thereof can be used in combination. When there are a plurality of substances corresponding to each component in the composition, unless particularly stated otherwise, the content of each component in the composition means the total amount of the plurality of substances present in the composition. In the present specification, the term “solid content” refers to a non-volatile content excluding volatile substances (water, solvent, and the like) included in the resin composition and also includes components that are liquid, syrup-like, or wax-like at room temperature (near 25° C.).

### [Maleimide Resin and Resin Composition]

A maleimide resin of the present embodiment is a maleimide resin obtained by reacting a tetracarboxylic acid dianhydride (a1) (hereinafter, also referred to as “component (a1)”), an amine (a2) (hereinafter, also referred to as “component (a2)”), and maleic anhydride (a3) (hereinafter, also referred to as “component (a3)”). Here, the component (a1) includes a tetracarboxylic acid dianhydride having a fluorene skeleton, the component (a2) includes a dimer diamine and an amine having a biphenyl skeleton, and the phenyl skeleton may have a lower alkyl (for example, methyl, ethyl, or propyl) as a substituent.

A resin composition of the present embodiment contains the above-described maleimide resin (A) (hereinafter, also referred to as “component (A)”). The resin composition of the present embodiment may further contain a polymerization initiator (B) (hereinafter, also referred to as “component (B)”). Furthermore, the resin composition of the present embodiment may further contain an organic solvent (C) (hereinafter, also referred to as “component (C)”).

### (Component (A): Maleimide Resin)

The component (A) can be obtained by reacting the component (a1), component (a2), and component (a3). The component (A) may have a plurality of maleimide groups within the molecule. The component (A) may be a bismaleimide resin.

The tetracarboxylic acid dianhydride of the component (a1) includes a tetracarboxylic acid dianhydride having a fluorene skeleton. From the viewpoint of low dielectric characteristics, high Tg, or low linear expansion coefficient (CTE), it is preferable that the component (a1) contains at least one of 9,9-bis(3,4-dicarboxyphenyl) fluorene dianhydride and 9,9-bis[4-(3,4-dicarboxyphenoxy)phenyl]fluorene dianhydride as the tetracarboxylic acid dianhydride having a fluorene skeleton.

The component (a1) may further contain a tetracarboxylic acid dianhydride that does not have a fluorene skeleton. The tetracarboxylic acid dianhydride that does not have a fluorene skeleton may have a biphenyl skeleton or may have an aromatic ring other than biphenyl.

Examples of the tetracarboxylic acid dianhydride that does not have a fluorene skeleton include pyromellitic anhydride, 4,4′-(hexafluoroisopropylidene)diphthalic anhydride, 1,3,3a,4,5,9b-hexahydro-5 (tetrahydro-2,5-dioxo-3-furanyl) naphtho[1,2-C]furan-1,3-dione, 4,4′-oxydiphthalic anhydride, 3,3′,4,4′-diphenylsulfonetetracarboxylic acid dianhydride, 3,3′,4,4′-biphenyltetracarboxylic acid dianhydride, 2,3′,3,4′-biphenyltetracarboxylic acid dianhydride, 3,3′,4,4′-benzophenonetetracarboxylic acid dianhydride, 4,4′-(4,4′-isopropylidenediphenoxy)diphthalic anhydride, 1,2,3,4-butanetetracarboxylic acid dianhydride, 1,2,3,4-cyclobutanetetracarboxylic acid dianhydride, 1,2,3,4-cyclopentanetetracarboxylic acid dianhydride, 1,2,3,4-tetramethyl-1,2,3,4-cyclobutanetetracarboxylic acid dianhydride, bicyclo[2.2.2]oct-7-ene-2,3,5,6-tetracarboxylic acid dianhydride, bis(1,3-dioxo-1,3-dihydroisobenzofuran-5-carboxylic acid)-1,4-phenylene, 4,4′-(ethyne-1,2-diyl)diphthalic anhydride, 5-(2,5-dioxotetrahydrofuryl)-3-methyl-3-cyclohexene-1,2-dicarboxylic acid anhydride, dicyclohexyl-3,4,3′,4′-tetracarboxylic acid dianhydride, 3,4′-oxydiphthalic anhydride, 3,4′-biphthalic anhydride, norbornane-2-spiro-α-cyclopentanone-α′-spiro-2″-norbornane-5,5″,6,6″-tetracarboxylic acid dianhydride, and 5,5′-bis-2-norbornene-5,5′,6,6′-tetracarboxylic acid-5,5′,6,6′-dianhydride. These can be used singly or in combination of two or more kinds thereof.

The component (a2) includes a dimer diamine (first amine) and an amine having a biphenyl skeleton (second amine).

The dimer diamine is a compound derived from dimer acid, which is a dimer of an unsaturated fatty acid such as oleic acid, as described in, for example, Japanese Unexamined Patent Publication No. H9-12712. By using a dimer diamine as the component (a2), the dielectric characteristics of the cured product can be lowered. In the present embodiment, any known dimer diamine can be used without particular limitation. It is preferable that the dimer diamine includes, for example, at least one of a compound represented by the following general Formula (1) and a compound represented by the following general Formula (2).

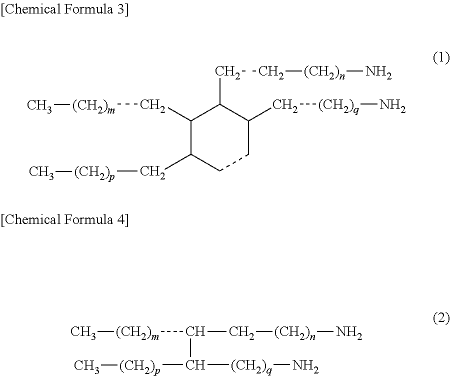

In Formulas (1) and (2), m, n, p, and q each represent an integer of 1 or greater selected such that m+n=6 to 17 and p+q=8 to 19, and a bond indicated by a dashed line means a carbon-carbon single bond or a carbon-carbon double bond. However, when a bond indicated by a dashed line is a carbon-carbon double bond, Formulas (1) and (2) have a structure in which the number of hydrogen atoms bonded to each of the carbon atoms constituting a carbon-carbon double bond is one less than the number shown in Formulas (1) and (2).

From the viewpoints of solubility in organic solvents, heat resistance, heat-resistant adhesiveness, low viscosity, and the like, the dimer diamine may be a compound represented by the above-described general Formula (2) and may be a compound represented by the following Formula (3) in particular.

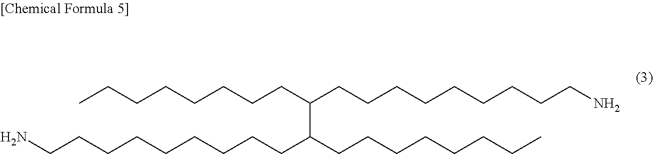

Examples of a commercially available product of the dimer diamine include PRIAMINE 1075 and PRIAMINE 1074 (all manufactured by Croda Japan K.K.). These can be used singly or in combination of two or more kinds thereof.

Examples of the amine having a biphenyl skeleton include 4,4′-diamino-2,2′-dimethylbiphenyl, 4,4′-diamino-2,2′-diethylbiphenyl, 4,4′-diamino-3,3′-dimethylbiphenyl, 4,4′-diamino-3,3′-diethylbiphenyl, 4,4′-diamino-3,3′,5,5′-tetramethylbiphenyl, 4,4′-diamino-3,3′,5,5′-tetraethylbiphenyl, 4,4′-diamino-2,2′-bis(trifluoromethyl) biphenyl, 4,4′-diamino-2,2′-dimethoxybiphenyl, and 4,4′-diamino-3,3′-dimethoxybiphenyl. The amine having a biphenyl skeleton may be a diamine having a biphenyl skeleton.

The component (a2) may further include a third amine other than a dimer diamine and an amine having a biphenyl skeleton. The third amine may be a diamine or a triamine, or may be a diamine. By using an alicyclic diamine as the third amine, the dielectric constant can be further lowered. By using an aromatic diamine as the third amine, the elastic modulus, Tg, and CTE of the cured product can be improved.

When the third amine is a diamine, examples of the diamine include 1,3-diaminopropane, norbornanediamine, 4,4-methylenedianiline, 1,3-bis[2-(4-aminophenyl)-2-propyl]benzene, 2,2-bis[4-(4-aminophenoxy)phenyl]hexafluoropropane, 9,9-bis(4-aminophenyl) fluorene, 9,9-bis[3-fluoro-4-aminophenyl]fluorene, 9,9-bis[4-(4-aminophenoxy)phenyl]fluorene, 1,3-bis(aminomethyl)cyclohexane, 1,4-bis(aminomethyl)cyclohexane, bis(aminomethyl) norbornane, 4,4′-(hexafluoroisopropylidene)dianiline, 3 (4), 8 (9)-bis(aminomethyl)tricyclo[5.2.1.0^{2,6}]decane, 1,3-cyclohexanediamine, 1,4-cyclohexanediamine, isophoronediamine, 4,4′-methylenebis(cyclohexylamine), 4,4′-methylenebis(2-methylcyclohexylamine), 1,1-bis(4-aminophenyl)cyclohexane, 2,7-diaminofluorene, 4,4′-ethylenedianiline, 4,4′-methylenebis(2,6-diethylaniline), 4,4′-methylenebis(2-ethyl-6-methylaniline), 2,2-bis[4-(4-aminophenoxy)phenyl]propane, bis[4-(4-aminophenoxy)phenyl]methane, bis[4-(4-aminophenoxy)phenyl]ether, bis[4-(4-aminophenoxy)phenyl] ketone, 1,3-bis(4-aminophenoxy)benzene, 1,4-bis(4-aminophenoxy)benzene, (4,4′-diamino)diphenyl ether, (3,3′-diamino)diphenyl ether, para-phenylenediamine, ortho-phenylenediamine, meta-phenylenediamine, bis[4-(3-aminophenoxy)phenyl]sulfone, and bis[4-(4-aminophenoxy)phenyl]sulfone. These can be used singly or in combination of two or more kinds thereof.

When the third amine is a triamine, examples of the triamine include tris(2-aminomethyl)amine, tris(2-aminoethyl)amine, tris(2-aminopropyl)amine, 2-(aminomethyl)-2-methyl-1,3-propanediamine, trimer triamine, 3,4,4′-triaminodiphenyl ether, 1,2,4-triaminobenzene, 1,3,5-triaminobenzene, 1,2,3-triaminobenzene, 1,3,5-triazine-2,4,6-triamine, 2,4,6-triaminopyrimidine, 1,3,5-tris(4-aminophenyl)benzene, and 1,3,5-tris(4-aminophenoxy)benzene. These can be used singly or in combination of two or more kinds thereof. Among these, from the viewpoint of the solubility of the synthesized component (A) in organic solvents, an aliphatic triamine is preferred, and furthermore, tris(2-aminomethyl)amine and tris(2-aminoethyl)amine, which have a small number of carbon atoms, are more preferred from the viewpoint of obtaining a higher Tg.

The third amine may include either the diamine or the triamine, or may include both of them. Furthermore, the third amine may include an amine other than a diamine and a triamine.

In the component (a2), the molar ratio of the second amine to the total amount of amines (number of moles of second amine/(number of moles of dimer diamine+number of moles of second amine)) may be 70 mol % or less, or may be 50 mol % or less. When this ratio is 70 mol % or less, the dielectric characteristics of the cured product can be further lowered.

By using a dimer diamine as the diamine, the dielectric characteristics of the cured product can be lowered. On the other hand, by using only a dimer diamine as the amine, the elastic modulus and Tg of the cured product are decreased, and the CTE is increased. In contrast, by using an amine having a biphenyl skeleton in combination with a dimer diamine, the elastic modulus, Tg, CTE, and toughness of the cured product can be improved while maintaining the dielectric characteristics of the cured product.

The component (A) can be produced by various known methods. For example, first, the component (a1) and the component (a2) are subjected to a polyaddition reaction at a temperature of about 60° C. to 120° C., and preferably 70° C. to 90° C., usually for about 0.1 to 2 hours, and preferably 0.1 to 1.0 hour. Next, the obtained polyaddition product is further subjected to an imidation reaction, that is, a dehydration ring-closing reaction, at a temperature of about 80° C. to 250° C., and preferably 100° C. to 200° C., for about 0.5 to 30 hours, and preferably 0.5 to 10 hours. Subsequently, the product obtained by the dehydration ring-closing reaction and the component (a3) are subjected to a maleimidation reaction, that is, a dehydration ring-closing reaction, at a temperature of about 60° C. to 250° C., and preferably 80° C. to 200° C., for about 0.5 to 30 hours, and preferably 0.5 to 10 hours, and thereby the intended component (A) is obtained.

In the imidation reaction or maleimidation reaction, various known reaction catalysts and dehydrating agents, and organic solvents that will be described below can be used. Examples of the reaction catalysts include aliphatic tertiary amines such as triethylamine; aromatic tertiary amines such as dimethylaniline; heterocyclic tertiary amines such as pyridine, picoline, and isoquinoline; and organic acids such as methanesulfonic acid and paratoluenesulfonic acid monohydrate. These can be used singly or in combination of two or more kinds thereof. Examples of the dehydrating agents include aliphatic acid anhydrides such as acetic anhydride; and aromatic acid anhydrides such as benzoic anhydride. These can be used singly or in combination of two or more kinds thereof.

The component (A) can be purified by various known methods, and the purity can be increased. For example, first, the component (A) dissolved in a solvent and pure water are placed in a separatory funnel. Next, the separatory funnel is shaken and left to stand still. Subsequently, after an aqueous layer and an organic layer are separated, the component (A) can be purified by collecting only the organic layer.

An example of the assumed structure of the component (A) produced by the above-described method is represented by the following general Formula (4). The general Formula (4) is an assumption that the component (a2) is a diamine.

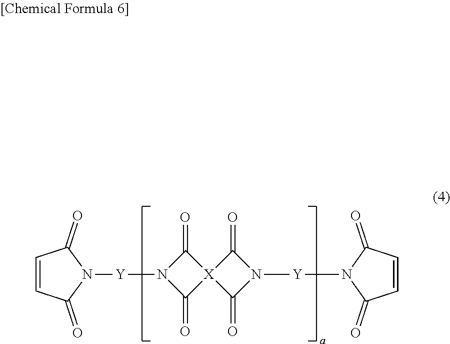

In the general Formula (4), X's each independently represents a tetravalent organic group; Y's each independently represent a divalent organic group; and a represents an integer of 1 or greater. However, at least one of a plurality of Y's present therein represents a divalent organic group derived from a dimer diamine, while at least one of a plurality of Y's present therein represents a divalent organic group derived from the above-mentioned amine having a biphenyl skeleton. Furthermore, at least one of the plurality of X's present in the formula represents a tetravalent organic group having a fluorene skeleton.

The molecular weight of the component (A) can be controlled by the number of moles of the component (a1) and the component (a2), and as the number of moles of the component (a1) is smaller than the number of moles of the component (a2), the molecular weight can be made smaller. For the purpose of easily achieving the effects of the present disclosure, usually, the number of moles of the component (a1) with respect to 1 mole of the component (a2), that is, [number of moles of component (a1)]/[number of moles of component (a2)], is in the range of about 0.30 to 0.98, preferably 0.40 to 0.96, more preferably 0.50 to 0.94, and even more preferably 0.60 to 0.90.

From the viewpoints of solubility in solvents and heat resistance, the molecular weight of the component (A) as the weight average molecular weight (Mw) is preferably 3000 to 40000, and may be 4000 to 30000, 5000 to 28000, 7000 to 27000, or 8000 to 26500. When the weight average molecular weight is 40000 or less, the solubility in organic solvents is improved, and when the weight average molecular weight is 3000 or more, a sufficient effect of improving heat resistance tends to be obtained. The Mw can be measured by gel permeation chromatography (GPC) and calculated using a calibration curve of polystyrene standards.

The component (A) can be used singly or in combination of two or more kinds thereof.

### (Component (B): Polymerization Initiator)

As a component (B), various known polymerization initiators can be used without particular limitation as long as they are polymerization initiators that can be used in resin compositions. Specific examples of the component (B) include an organic peroxide, an imidazole compound, a phosphine compound, and a phosphonium salt compound. These can be used singly or in combination of two or more kinds thereof. Among these, an organic peroxide and an imidazole compound are particularly preferred because they have an excellent function as polymerization initiator and are also excellent in terms of low dielectric characteristics.

Examples of the organic peroxide include methyl ethyl ketone peroxide, methyl cyclohexanone peroxide, methyl acetoacetate peroxide, acetyl acetone peroxide, 1,1-bis(t-butylperoxy)-3,3,5-trimethylcyclohexane, 1,1-bis(t-hexylperoxy)cyclohexane, 1,1-bis(t-hexylperoxy)-3,3,5-trimethylcyclohexane, 1,1-bis(t-butylperoxy)cyclohexane, 2,2-bis(4,4-di-t-butylperoxycyclohexyl) propane, 1,1-bis(t-butylperoxy)cyclododecane, n-butyl-4,4-bis(t-butylperoxy) valerate, 2,2-bis(t-butylperoxy) butane, 1,1-bis(t-butylperoxy)-2-methylcyclohexane, t-butyl hydroperoxide, p-menthane hydroperoxide, 1,1,3,3-tetramethylbutyl hydroperoxide, t-hexyl hydroperoxide, dicumyl peroxide, 2,5-dimethyl-2,5-bis(t-butylperoxy) hexane, α,α′-bis(t-butylperoxy)diisopropylbenzene, t butylcumyl peroxide, di-t-butyl peroxide, 2,5-dimethyl-2,5-bis(t-butylperoxy) hexyne-3, isobutyryl peroxide, 3,5,5-trimethylhexanoyl peroxide, octanoyl peroxide, lauroyl peroxide, cinnamic acid peroxide, m-toluoyl peroxide, benzoyl peroxide, diisopropyl peroxydicarbonate, bis(4-t-butylcyclohexyl) peroxydicarbonate, di-3-methoxybutyl peroxydicarbonate, di-2-ethylhexyl peroxydicarbonate, di-sec-butyl peroxydicarbonate, di(3-methyl-3-methoxybutyl) peroxydicarbonate, di(4-t-butylcyclohexyl) peroxydicarbonate, α,α′-bis(neodecanoylperoxy)diisopropylbenzene, cumyl peroxyneodecanoate, 1,1,3,3-tetramethylbutyl peroxyneodecanoate, 1-cyclohexyl-1-methylethyl peroxyneodecanoate, t-hexyl peroxyneodecanoate, t-butyl peroxyneodecanoate, t-hexyl peroxypivalate, t-butyl peroxypivalate, 2,5-dimethyl-2,5-bis(2-ethylhexanoylperoxy) hexane, 1,1,3,3-tetramethylbutyl peroxy-2-ethylhexanoate, 1-cyclohexyl-1-methylethyl peroxy-2-ethylhexanoate, t-hexyl peroxy-2-ethylhexanoate, t-butyl peroxy-2-ethylhexanoate, t-butyl peroxyisobutyrate, t-butyl peroxymaleic acid, t-butyl peroxylaurate, t-butyl peroxy-3,5,5-trimethylhexanoate, t-butyl peroxyisopropyl monocarbonate, t-butyl peroxy-2-ethylhexyl monocarbonate, 2,5-dimethyl-2,5-bis(benzoylperoxy) hexane, t-butyl peroxyacetate, t-hexyl peroxybenzoate, t-butyl peroxy-m-toluoyl benzoate, t-butyl peroxybenzoate, bis(t-butylperoxy) isophthalate, t-butyl peroxyallyl monocarbonate, and 3,3′,4,4′-tetra(t-butylperoxycarbonyl)benzophenone. These can be used singly or in combination of two or more kinds thereof. Among these organic peroxides, dicumyl peroxide, 2,5-dimethyl-2,5-bis(t-butylperoxy) hexane, α,α′-bis(t-butylperoxy)diisopropylbenzene, and the like are preferred.

Examples of the imidazole compound include 2-ethyl-4-methylimidazole, 2-methylimidazole, 2-ethylimidazole, 2,4-dimethylimidazole, 2-undecylimidazole, 2-heptadecylimidazole, 2-phenylimidazole, 2-phenyl-4-methylimidazole, 1-benzyl-2-methylimidazole, 2-phenyl-4,5-dihydroxymethylimidazole, 2-phenyl-4-methyl-5-hydroxymethylimidazole, 1-vinyl-2-methylimidazole, 1-propyl-2-methylimidazole, 2-isopropylimidazole, 1-cyanomethyl-2-methylimidazole, 1-cyanoethyl-2-ethyl-4-methylimidazole, 1-cyanoethyl-2-undecylimidazole, and 1-cyanoethyl-2-phenylimidazole. Among them, 1-cyanoethyl-2-phenylimidazole and 2-ethyl-4-methylimidazole have high solubility in the resin composition of the present embodiment and are preferred. These can be used singly or in combination of two or more kinds thereof.

Examples of the phosphine compound include a primary phosphine, a secondary phosphine, and a tertiary phosphine. Examples of the primary phosphine include alkylphosphines such as ethylphosphine and propylphosphine; and phenylphosphine. Examples of the secondary phosphine include dialkylphosphines such as dimethylphosphine and diethylphosphine; and secondary phosphines such as diphenylphosphine, methylphenylphosphine, and ethylphenylphosphine. Examples of the tertiary phosphine include trialkylphosphines such as trimethylphosphine, triethylphosphine, tributylphosphine, and trioctylphosphine; tricyclohexylphosphine, triphenylphosphine, alkyldiphenylphosphine, dialkylphenylphosphine, tribenzylphosphine, tritolylphosphine, tri-p-styrylphosphine, tris(2,6-dimethoxyphenyl)phosphine, tri-4-methylphenylphosphine, tri-4-methoxylphenylphosphine, and tri-2-cyanoethylphosphine. Among them, the tertiary phosphine is preferably used. These can be used singly or in combination of two or more kinds thereof.

Examples of the phosphonium salt compound include compounds having a tetraphenylphosphonium salt, an alkyltriphenylphosphonium salt, a tetraalkylphosphonium, and the like, and specific examples thereof include tetraphenylphosphonium thiocyanate, tetraphenylphosphonium tetra-p-methylphenylborate, butyltriphenylphosphonium thiocyanate, tetraphenylphosphonium phthalic acid, tetrabutylphosphonium 1,2-cyclohexyldicarboxylic acid, tetrabutylphosphonium 1,2-cyclohexyldicarboxylic acid, and tetrabutylphosphonium lauric acid. These can be used singly or in combination of two or more kinds thereof.

The content of the component (B) is not particularly limited and may be 0.1 to 10.0 parts by mass, 0.2 to 5.0 parts by mass, 0.3 to 3.0 parts by mass, 0.3 to 2.0 parts by mass, or 0.3 to 1.0 parts by mass, with respect to 100 parts by mass of the component (A).

### (Component (C): Organic Solvent)

A component (C) is not particularly limited as long as it can dissolve the component (A). Examples of the component (C) include aromatic hydrocarbon-based solvents such as benzene, toluene, xylene, mesitylene, pseudocumene, and anisole; alcohol-based solvents such as methanol, ethanol, isopropyl alcohol, butanol, pentanol, hexanol, propanediol, and phenol; ketone-based solvents such as acetone, methyl isobutyl ketone, methyl ethyl ketone, pentanone, hexanone, cyclopentanone, cyclohexanone, isophorone, and acetophenone; cellosolves such as methyl cellosolve and ethyl cellosolve; ester-based solvents such as methyl acetate, ethyl acetate, butyl acetate, methyl propionate, butyl formate, and γ-butyrolactone; glycol ether-based solvents such as ethylene glycol mono-n-butyl ether, ethylene glycol mono-isobutyl ether, ethylene glycol mono-tert-butyl ether, diethylene glycol mono-n-butyl ether, diethylene glycol mono-iso-butyl ether, triethylene glycol mono-n-butyl ether, and tetraethylene glycol mono-n-butyl ether; and amide-based solvents such as N,N-dimethylformamide, N,N-dimethylacetamide, N-methyl-2-pyrrolidone, and N-ethyl-2-pyrrolidone. These can be used singly or in combination of two or more kinds thereof. Among these, it is preferable to use an aromatic hydrocarbon such as toluene or mesitylene, which has high dissolvability for the component (A).

The use amount of the component (C) is not particularly limited; however, usually, the component (C) may be used in a range such that the non-volatile content of the resin composition of the present embodiment is about 20% to 65% by mass.

Preparation of the resin composition of the present embodiment is carried out according to a method that is generally employed. Examples of the method for preparation include methods such as melt mixing, powder mixing, and solution mixing. Furthermore, in this case, agents other than the essential components of the present embodiment, for example, a mold release agent, a flame retardant, an ion trapping agent, an antioxidant, a tackifier, a stress reducing agent, a colorant, a coupling agent, and an inorganic filler material may be blended to the extent that does not impair the effects of the present disclosure. Furthermore, the resin composition of the present embodiment may contain a resin other than the above-described component (A), such as an epoxy resin, a (meth)acrylate compound, a vinyl compound, a benzoxazine compound, and a maleimide compound other than the above-described component (A).

### (Mold Release Agent)

A mold release agent is added to improve releasability from a mold. As the mold release agent, for example, any known mold release agents can be used, such as carnauba wax, rice wax, candelilla wax, polyethylene, polyethylene oxide, polypropylene, montanic acid, montan wax which is an ester compound of montanic acid with saturated alcohol, 2-(2-hydroxyethylamino) ethanol, ethylene glycol, glycerin, or the like, stearic acid, stearic acid ester, and stearic acid amide. These can be used singly or in combination of two or more kinds thereof.

### (Flame Retardant)

A flame retardant is added to impart flame retardancy, and any known flame retardants can be used without particular limitation. Examples of the flame retardant include a phosphazene compound, a silicon compound, zinc molybdate-supported talc, zinc molybdate-supported zinc oxide, aluminum hydroxide, magnesium hydroxide, and molybdenum oxide. These can be used singly or in combination of two or more kinds thereof.

### (Ion Trapping Agent)

An ion trapping agent is added to capture ionic impurities contained in a liquid resin composition and to prevent thermal deterioration and hygroscopic deterioration. Any known ion trapping agents can be used and are not particularly limited. Examples of the ion trapping agent include hydrotalcite, bismuth hydroxide compound, and rare earth oxides. These can be used singly or in combination of two or more kinds thereof.

### (Inorganic Filler Material)

Various known inorganic filler materials can be used without particular limitation as long as they are inorganic filler materials that can be used in a resin composition. Examples of the inorganic filler material include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whiskers, boron nitride, silica, graphite powder, and boehmite. Among these, silica in particular is preferred because it is excellent in terms of low dielectric loss tangent. The inorganic filler material can be used singly or in combination of two or more kinds thereof.

The average particle size of the inorganic filler material may be 50 nm or more, 100 nm or more, or 200 nm or more, and may be 10 μm or less, 5.0 μm or less, 3.0 μm or less, or 1.0 μm or less. The average particle size of the inorganic filler material is preferably 100 nm to 10 μm or 50 nm to 5.0 μm, more preferably 100 nm to 3.0 μm, and even more preferably 200 nm to 1.0 μm. When the average particle size of the inorganic filler material is in the above-described range, the surface roughness of the sheet can be decreased, and the adhesiveness to substrates such as a polyimide film and a copper foil can be increased.

As the average particle size of the above-described inorganic filler material, the value of a median diameter (d50) at which the cumulative particle size in the volume cumulative particle size distribution is 50%, is employed. The above-described average particle size can be measured using a laser diffraction scattering type particle size distribution analyzer.

It is preferable that the inorganic filler material is surface-treated, it is preferable that the inorganic filler material is a product surface-treated with a coupling agent, and more preferably a product surface-treated with a silane coupling agent. As the above-described inorganic filler material is surface-treated, not only is it possible to increase the dispersibility of the inorganic filler material in an organic solvent, but also the surface roughness of the surface of the sheet can be further reduced, and the adhesiveness to substrates such as a polyimide film and a copper foil can be increased.

Examples of the coupling agent include a silane coupling agent, a titanium coupling agent, and an aluminum coupling agent. Examples of the above-described silane coupling agent include methacrylsilane, acrylsilane, aminosilane, phenylaminosilane, imidazolesilane, phenylsilane, vinylsilane, and epoxysilane. These can be used singly or in combination of two or more kinds thereof.

When the resin composition contains an inorganic filler material, the content thereof may be 5% to 75% by mass, 5% to 50% by mass, 5% to 35% by mass, or 10% to 30% by mass, based on the total amount of solid content (non-volatile content) of the resin composition (100% by mass). When the content of the inorganic filler material is 75% by mass or less, there is a tendency that deterioration of adhesiveness can be suppressed, and when the content is 5% by mass or more, an effect of reducing the dielectric loss tangent as well as an effect of improving heat resistance tend to be sufficiently obtained.

### [Cured Product]

A cured product of the present embodiment is a product obtained by curing the resin composition of the present embodiment. Specifically, the cured product can be obtained by subjecting the composition to a heating treatment at about 150° C. to 250° C. for about 10 minutes to 3 hours.

The shape of the cured product of the present embodiment is not particularly limited; however, when the cured product is submitted to a use application of adhering a substrate, the cured product can be in the form of a sheet having a film thickness of usually about 1 to 200 μm, and preferably about 3 to 100 μm, and the film thickness can be appropriately adjusted according to the use application.

### [Sheet]

The sheet of the present embodiment includes the resin composition of the present embodiment and a substrate. The sheet of the present embodiment is obtained by, for example, applying the resin composition of the present embodiment as a substrate (sheet substrate) and drying the resin composition. Examples of the substrate include organic substrates such as polyimide, a polyimide-silica hybrid, polyamide, polyethylene (PE), polypropylene (PP), polyethylene terephthalate (PET), polyethylene naphthalate (PEN), a polymethyl methacrylate resin (PMMA), a polystyrene resin (PSt), a polycarbonate resin (PC), an acrylonitrile-butadiene-styrene resin (ABS), and an aromatic polyester resin obtained from ethylene terephthalate, phenol, phthalic acid, hydroxynaphthoic acid or the like with parahydroxybenzoic acid (so-called liquid crystal polymer: manufactured by Kuraray Co., Ltd., “VECSTAR” or the like), and among these, a polyimide film, especially a polyimide-silica hybrid film, is preferred from the viewpoints of heat resistance, dimensional stability, and the like. Furthermore, as the above-described substrate, inorganic substrates such as glass; metals such as iron, aluminum, Alloy 42, and copper; ITO, silicon, and silicon carbide may also be used. The thickness of the above-described substrate can be appropriately set according to the use application.

### [Laminate]

A laminate of the present embodiment is obtained by further subjecting a substrate to thermocompression bonding onto the adhesive surface of the above-described sheet. As the substrate, for example, organic substrates such as polyimide, a polyimide-silica hybrid, polyamide, polyethylene (PE), polypropylene (PP), polyethylene terephthalate (PET), polyethylene naphthalate (PEN), a polymethyl methacrylate resin (PMMA), a polystyrene resin (PSt), a polycarbonate resin (PC), an acrylonitrile-butadiene-styrene resin (ABS), and an aromatic polyester resin obtained from ethylene terephthalate, phenol, phthalic acid, hydroxynaphthoic acid or the like with parahydroxybenzoic acid (liquid crystal polymer), can be used. Furthermore, as the above-described substrate, inorganic substrates such as glass; metals such as iron, aluminum, Alloy 42, and copper; ITO, silicon, and silicon carbide may also be used. The thickness of the above-described substrate can be appropriately set according to the use application. Furthermore, the laminate may be further subjected to a heating treatment.

### [Printed Substrate and Printed Wiring Board]

A printed substrate of the present embodiment is obtained by using the above-described sheet or by using the above-described laminate. The printed substrate of the present embodiment is obtained by, for example, further sticking the adhesive surface of the above-described sheet to the inorganic substrate surface of the above-described laminate. Regarding the printed substrate, it is preferable to use a polyimide film as the organic substrate and a metal foil (in particular, a copper foil) as the inorganic substrate. Then, the metal surface of such a printed substrate is subjected to soft etching to form a circuit, and the above-described sheet is further stuck on top of the circuit and hot-pressed to obtain a printed wiring board.

### EXAMPLES

Hereinafter, the present disclosure will be specifically described by way of Examples and Comparative Examples; however, the present disclosure is not intended to be limited to these. Incidentally, in each example, unless particularly stated otherwise, the units “parts” and “percentage (%)” are on a mass basis.

### Synthesis of Maleimide Resin

In order to synthesize maleimide resins, the following components (a1) to (a3), acid catalysts, and solvents were prepared.

### (Component (a1))

BPAF: 9,9-Bis(3,4-dicarboxyphenyl) fluorenic dianhydride (manufactured by JFE Chemical Corporation, trade name “BPAF”)

PMDA: Pyromellitic anhydride (manufactured by Daicel Corporation)

BISDA: 4,4′-(4,4′-Isopropylidenediphenoxy)diphthalic anhydride (manufactured by SABIC, trade name “BISDA-1000”)

S-BPDA: 3,3′,4,4′-Biphenyltetracarboxylic acid dianhydride (manufactured by JFE Chemical Corporation, trade name “BPDA”)

a-BPDA: 2,3′,3,4′-Biphenyltetracarboxylic acid dianhydride (manufactured by JFE Chemical Corporation, trade name “a-BPDA”)

ODPA: 4,4′-Oxydiphthalic anhydride (manufactured by Manac, Inc., trade name “ODPA”)

### (Component (a2))

DDA: Dimer diamine (manufactured by Croda Japan K.K., trade name “PRIAMINE 1075”)

mTBHG: 4,4′-Diamino-2,2′-dimethylbiphenyl (manufactured by Wakayama Seika Kogyo Co., Ltd., trade name “m-TB-HG”)

NBDA: Norbornanediamine (manufactured by Mitsui Fine Chemicals, Inc.)

TAEA: Tris(2-aminoethyl)amine (manufactured by Tokyo Chemical Industry Co., Ltd.)

### (Component (a3))

Maleic anhydride (manufactured by Fuso Chemical Co., Ltd.)

### (Acid Catalyst)

Aqueous solution of methanesulfonic acid (manufactured by BASF SE, trade name “Lutropur MSA”)

### (Solvent)

Pseudocumene (manufactured by Toyo Gosei Co., Ltd., aromatic high-boiling point solvent)

SOLMIX A-11 (manufactured by Japan Alcohol Trading Co., Ltd., alcohol-based solvent)

Toluene (manufactured by Yamaichi Chemical Industries Co., Ltd.)

γ-Butyrolactone (manufactured by FUJIFILM Wako Pure Chemical Corporation)

### Synthesis Example 1

34.38 parts by mass of 9,9-bis(3,4-dicarboxyphenyl)fluorenic dianhydride (BPAF), 135.84 parts by mass of pseudocumene, 1.922 parts by mass of SOLMIX A-11, and 31.00 parts by mass of γ-butyrolactone were introduced into a 0.3-L flask container equipped with a condenser, a nitrogen inlet tube, a thermocouple, and a stirrer. After the introduction, the temperature was raised to 80° C. and kept at that temperature for 0.5 hours, 26.85 parts by mass of a dimer diamine (DDA) was added dropwise thereto, and then 10.62 parts by mass of 4,4′-diamino-2,2′-dimethylbiphenyl (mTBHG) was added thereto. After the addition, 1.92 parts by mass of an aqueous solution of methanesulfonic acid was added thereto, and the temperature was raised to 160° C. After raising the temperature, 40.00 parts by mass of toluene was added thereto, a dehydration ring-closing reaction was carried out at 160° C. for 1 hour, water and alcohol in the reaction liquid were removed, and a polyimide resin as an intermediate was obtained. Subsequently, the polyimide resin was cooled to 130° C., 7.36 parts by mass of maleic anhydride was added thereto, the temperature was raised to 160° C., a dehydration ring-closing reaction was carried out at 160° C. for 4 hours, water in the reaction liquid was removed, and a maleimide resin was obtained.

The maleimide resin was placed in a separatory funnel, 500 parts by mass of pure water was introduced therein, and the separatory funnel was shaken to mix the contents and allowed to stand still. After the standing, an aqueous layer and an organic layer were separated, and then only the organic layer was collected. The collected organic layer was introduced into a 1-L glass container equipped with a condenser, a nitrogen inlet tube, a thermocouple, a stirrer, and a vacuum pump, the temperature was raised to 88° C. to 93° C., water was removed, subsequently the temperature was raised to 100° C., the solvent was partially removed for 0.5 hours at a pressure reduced by 0.1 MPa from the atmospheric pressure, and a solution of a maleimide resin (A-1) of the component (A) was obtained.

### Synthesis Example 2

The blending table of each component was changed as shown in Table 1, and a maleimide resin before purification was obtained. 500 g of isopropanol (manufactured by FUJIFILM Wako Pure Chemical Corporation) was introduced into a 1-L glass container equipped with a stirrer. Subsequently, the obtained maleimide resin was introduced therein while being stirred at 300 rpm, and the mixture was further stirred for 30 minutes to perform reprecipitation. The reprecipitated maleimide resin was collected. The collected maleimide resin and 500 g of isopropanol were introduced into a 1-L glass container, and the contents were stirred at 300 rpm for 30 minutes. After the stirring, the maleimide resin was collected and dried at 70° C. for 12 hours, and a maleimide resin (A-2) of the component (A) was obtained.

### Synthesis Examples 3 to 9

Solutions of maleimide resins (A-3) to (A-9) were obtained in the same manner as in Synthesis Example 1, except that the blending amount of each component was changed as shown in Table 1.

### Synthesis Examples 10 and 12 to 14

Solutions of maleimide resins (A-10) and (A-12) to (A-14) were obtained in the same manner as in Synthesis Example 1, except that the blending amount of each component was changed as shown in Table 2.

### Synthesis Example 11

A maleimide resin (A-11) was obtained in the same manner as in Synthesis Example 2, except that the blending amount of each component was changed as shown in Table 2.

### Synthesis Examples 15 to 19

Solutions of maleimide resins (A-15) to (A-19) were obtained in the same manner as in Synthesis Example 1, except that the blending amount of each component was changed as shown in Table 3.

### (Non-Volatile Content)

0.75 g±0.25 g of each of solutions of maleimide resins (A-1), (A-3) to (A-10), (A-12) to (A-14), and (A-15) to (A-19) and powders of maleimide resins (A-2) and (A-11) was weighed out on a precision balance and placed in a metal Petri dish, subsequently the solution or powder was dried in a hot air dryer at 150° C. for 0.5 hours, and the non-volatile content (NV) was calculated from the following formula.

$$NV ( \% by mass ) = \{ ( W 3 - W 1 ) / W 2 \} \times 100$$

W1: Mass (g) of blank metal Petri dish
W2: Mass (g) of the solution or powder of the maleimide resin before drying
W3: Mass (g) of the metal Petri dish+maleimide resin after drying

### (Weight Average Molecular Weight)

The weight average molecular weight (Mw) of the maleimide resin was measured by GPC (gel permeation chromatography). A sample was obtained by dissolving the maleimide resin in tetrahydrofuran (THF) to a concentration of 3% by mass, 50 μL of the sample was injected into columns heated to 30° C. (one unit of GL-R420 (manufactured by Hitachi High-Tech Fielding Corporation), one unit of GL-R430 (manufactured by Hitachi High-Tech Fielding Corporation), and one unit of GL-R440 (manufactured by Hitachi High-Tech Fielding Corporation), and measurement was performed using THE as a developing solvent under the conditions of a flow rate of 1.6 mL/min. Incidentally, an L-3350 RI detector (manufactured by Hitachi, Ltd.) was used as the detector, and the Mw was calculated from the elution time based on a molecular weight/elution time curve created using polystyrene standards (manufactured by Tosoh Corporation). Incidentally, the maleimide resin (A-11) of Synthesis Example 11 was insoluble in THE, and therefore, the Mw could not be measured.

TABLE 1

| | | A-1 | A-2 | A-3 | A-4 | A-5 | A-6 | A-7 | A-8 | A-9 |
|---|---|---|---|---|---|---|---|---|---|---|
| (a1) | PMDA | — | — | — | — | 9.00 | 9.73 | 10.31 | 8.80 | — |
| | BPAF | 34.38 | 37.82 | 35.07 | 37.13 | 18.91 | 20.46 | 21.66 | 18.48 | 22.93 |
| | s-BPDA | — | — | — | — | — | — | — | — | 7.36 |
| (a2) | DDA | 26.85 | 17.72 | 24.16 | 24.16 | 29.53 | 28.19 | 28.19 | 25.98 | 24.19 |
| | mTBHG | 10.62 | 16.35 | 9.55 | 9.55 | 11.68 | 11.15 | 11.15 | 10.28 | 9.55 |
| | TAEA | — | — | — | — | — | — | — | 1.052 | 0.979 |
| (a3) | Maleic | 7.36 | 8.09 | 3.97 | 2.65 | 8.09 | 4.63 | 3.09 | 7.93 | 7.36 |
| | anhydride | | | | | | | | | |
| Acid | Aqueous | 1.92 | 2.11 | 1.04 | 0.69 | 2.11 | 1.21 | 0.81 | 3.84 | 3.59 |
| catalyst | solution of | | | | | | | | | |
| | methanesulfonic | | | | | | | | | |
| | acid | | | | | | | | | |
| Solvent | Pseudocumene | 135.84 | 136.16 | 129.91 | 133.75 | 131.01 | 131.65 | 134.95 | 123.49 | 124.17 |
| | SOLMIX A-11 | 1.92 | 30.05 | 27.95 | 28.65 | 29.11 | 28.99 | 29.59 | 33.45 | 32.58 |
| | Toluene | 40.00 | 40.00 | 40.00 | 40.00 | 40.00 | 40.00 | 40.00 | 40.00 | 40.00 |
| | γ-Butyrolactone | 31.00 | 31.00 | 30.00 | 30.00 | 30.00 | 30.00 | 30.00 | 29.94 | 33.20 |

| | | | | | | | | | |
|---|---|---|---|---|---|---|---|---|---|
| Molar ratio of (a1)/(a2) | 0.75 | 0.75 | 0.85 | 0.90 | 0.75 | 0.85 | 0.90 | 0.75 | 0.75 |
| N.V. (% by mass) | 45.5 | 96.0 | 39.8 | 35.6 | 43.5 | 39.6 | 36.7 | 39.2 | 36.5 |
| Mw | 9700 | 8400 | 17300 | 25700 | 9300 | 17300 | 26100 | 16900 | 17800 |

TABLE 2

| | | A-10 | A-11 | A-12 | A-13 | A-14 |
|---|---|---|---|---|---|---|
| (a1) | PMDA | — | 21.27 | — | — | 18.00 |
| | BPAF | — | — | 34.38 | 27.50 | — |
| | BISDA | 35.1 | — | — | — | — |
| (a2) | DDA | 24.16 | 34.90 | 26.85 | 42.95 | 59.06 |
| | mTBHG | 9.55 | 13.80 | — | — | — |
| | NBDA | — | — | 7.71 | — | — |
| (a3) | Maleic anhydride | 6.62 | 9.56 | 7.36 | 5.88 | 8.09 |
| Acid | Aqueous solution of | 1.73 | 2.50 | 1.92 | 1.54 | 2.11 |
| catalyst | methanesulfonic acid | | | | | |
| Solvent | Pseudocumene | 129.97 | 133.08 | 130.45 | 132.78 | 145.76 |
| | SOLMIX A-11 | 27.96 | 30.45 | 28.53 | 27.99 | 31.79 |
| | Toluene | 40.00 | 40.00 | 40.00 | 40.00 | 40.00 |
| | γ-Butyrolactone | 30.00 | 30.00 | 30.00 | — | — |

| | | | | | |
|---|---|---|---|---|---|
| Molar ratio of (a1)/(a2) | 0.75 | 0.75 | 0.75 | 0.75 | 0.75 |
| N.V. (% by mass) | 57.5 | 94.5 | 47.2 | 54.5 | 54.3 |
| Mw | 12200 | — | 11200 | 15500 | 16700 |

TABLE 3

| | | A-15 | A-16 | A-17 | A-18 | A-19 |
|---|---|---|---|---|---|---|
| (a1) | PMDA | — | — | 9.01 | 8.80 | 7.95 |
| | BPAF | 16.87 | 17.63 | 18.93 | 18.48 | 16.68 |
| | OPDA | 11.42 | — | — | — | — |
| | a-BPDA | — | 11.33 | — | — | — |
| (a2) | DDA | 26.36 | 27.52 | 27.61 | 27.57 | 25.35 |
| | mTBHG | 8.34 | 8.72 | 10.87 | 10.85 | 10.00 |
| | TAEA | 0.96 | 1.01 | 0.75 | 0.52 | 0.29 |
| (a3) | Maleic anhydride | 7.24 | 7.56 | 8.13 | 7.93 | 7.17 |
| Acid | Aqueous solution of | 3.52 | 3.68 | 3.94 | 3.86 | 3.49 |
| catalyst | methanesulfonic acid | | | | | |
| Solvent | Pseudocumene | 121.64 | 126.50 | 127.95 | 125.90 | 114.77 |
| | SOLMIX A-11 | 34.41 | 34.60 | 35.29 | 33.60 | 30.52 |
| | Toluene | 40.00 | 40.00 | 40.00 | 40.00 | 40.00 |
| | γ-Butyrolactone | 29.43 | 30.57 | 30.98 | 33.25 | 28.24 |

| | | | | | |
|---|---|---|---|---|---|
| Molar ratio of (a1)/(a2) | 0.75 | 0.75 | 0.75 | 0.75 | 0.75 |
| N.V. (% by mass) | 42.3 | 44.8 | 43.2 | 42.9 | 46.5 |
| Mw | 17700 | 15800 | 13600 | 11900 | 10900 |

### Examples 1 to 14 and Comparative Examples 1 to 5

### Preparation of Resin Composition

Each component shown below was blended in the composition shown in Table 4 to prepare maleimide resin compositions of Examples 1 to 9. Each component shown below was blended in the composition shown in Table 5 to prepare maleimide resin compositions of Examples to 14. Each component shown below was blended in the composition shown in Table 6 to prepare maleimide resin compositions of Comparative Examples. The blending amount of the component (A) shown in Tables 4 to 6 indicates a blending amount (parts by mass) including the solvent. Incidentally, the maleimide resin composition of Comparative Example 2 using the maleimide resin (A-11) was insoluble in the solvent and therefore could not be evaluated.

### Component (A): Maleimide Resin

Maleimide resins (A-1) to (A-19) produced in Synthesis Examples 1 to 19

### Component (B): Polymerization Initiator

(B-1) DCP (manufactured by NOF Corporation, trade name “PERCUMYL D”, dicumyl peroxide)

### Component (C): Organic Solvent

(C-1) Toluene (manufactured by Yamaichi Chemical Industries Co., Ltd.)

(C-2) DMF (N,N-dimethylformamide)

### Preparation of Cured Sheet

The above-described maleimide resin composition was applied on a Cu foil (manufactured by Mitsui Mining & Smelting Co., Ltd., trade name “3EC-M2S-VLP”) using an applicator such that the thickness after drying would be 100 μm, and the maleimide resin composition was subjected to a drying treatment in a dryer at 130° C. for 30 minutes. Subsequently, the dried maleimide resin composition was subjected to a curing treatment in a nitrogen dryer at 200° C. for 1 hour. After the curing, the resultant was cooled to room temperature, subsequently the copper foil was etched with an aqueous solution of ammonium persulfate, and the cured maleimide resin composition was dried at 110° C. for 30 minutes to prepare a cured sheet.

### [Measurement of Elastic Modulus and Tg]

A test piece having a sample size of 20 mm×10 mm was prepared using the cured sheet, and the elastic modulus at 20° C. and the Tg (tan & peak) were measured using a dynamic viscoelasticity measuring apparatus (manufactured by SII Nanotechnology, Inc., trade name “DMS6100”) under the conditions of a frequency of 1 Hz, a measurement temperature of −40° C. to 220° C., and a temperature increase rate of 10° C./min.

### [Linear Expansion Coefficient]

A test piece having a size of 30 mm×4 mm was prepared from the cured sheet. Using this test piece, the linear expansion coefficient (CTE) was measured using a thermomechanical analysis apparatus (trade name “TMA/SS7100”, manufactured by Hitachi High-Tech Science Corporation). The measurement mode was tensile mode, the measurement load was 50 mN, the measurement atmosphere was air atmosphere, the temperature increase rate was set to 5° C./min, and the measurement result obtained in the 2^{nd} run at −20° C. to 40° C. was taken as the CTE.

### [5% Weight Loss Temperature]

6.0 to 10.0 mg of the cured sheet was measured out and placed in an open type sample container (manufactured by Seiko Electronics Co., Ltd., trade name “P/N SSC000E030”), measurement was made under the conditions of a nitrogen flow rate of 300 mL/min and a temperature increase rate of 10° C./min, and the 5% weight loss temperature (Tas) was measured. Regarding the measuring apparatus, TG/DTA7200 (manufactured by Hitachi High-Tech Science Corporation) was used.

### [Evaluation of Dielectric Characteristics]

A test piece having a sample size of 50 mm×100 mm was prepared using the cured sheet. Using this test piece, the relative dielectric constant (Dk) and the dielectric loss tangent (Df) at 10 GHz were measured using a network analyzer (manufactured by KEYSIGHT Technologies, Inc., trade name “P5003A”) and a split cylinder resonator (manufactured by KEYSIGHT Technologies, Inc.). The measurement results were evaluated based on the following determination criteria. When the evaluation result is A or B, it can be said that the dielectric characteristics are sufficiently low.

### <Determination Criteria for Dk>

A: Less than 2.5
B: 2.5 or more and less than 2.8
C: 2.8 or more

### <Determination Criteria for Df>

A: Less than 0.0030
B: 0.0030 or more and less than 0.0050
C: 0.0050 or more

### [Evaluation of Toughness]

The above-described maleimide resin composition was applied on a FILMBYNA (registered trademark) (PET Film, manufactured by Fujimori Kogyo Co., Ltd., trade name “NS14”, thickness 75 μm) such that the thickness after drying would be 50 μm, the applied maleimide resin composition was subjected to a drying treatment in a dryer at 130° C. for 30 minutes, and an adhesive sheet was obtained. A test piece having a sample size of 10 mm×50 mm was prepared using the adhesive sheet, and the minimum diameter at which the adhesive sheet broke was measured using a mandrel testing machine. The measurement results were evaluated based on the following determination criteria.

TABLE 4
<Determination criteria for toughness>

| | | Example | | | | | | | | |
|---|---|---|---|---|---|---|---|---|---|---|
| | | 1 | 2 | 3 | 4 | 5 | 6 | 7 | 8 | 9 |
| Component | A-1 | 100 | — | — | — | — | — | — | — | — |
| (A) | A-2 | — | 100 | — | — | — | | — | — | — |
| | A-3 | — | — | 100 | — | — | — | | — | — |
| | A-4 | — | — | — | 100 | — | — | — | — | — |
| | A-5 | — | — | — | — | 100 | — | — | — | — |
| | A-6 | — | — | — | — | — | 100 | — | — | — |
| | A-7 | — | — | — | — | — | — | 100 | — | — |
| | A-8 | — | | | — | | | | 100 | — |
| | A-9 | — | — | — | — | — | — | | | 100 |
| Component | DCP | 0.46 | 0.96 | 0.40 | 0.36 | 0.44 | 0.40 | 0.37 | 0.39 | 0.37 |
| (B) | | | | | | | | | | |
| Organic | Toluene | — | — | — | — | — | | | | — |
| solvent | DMF | — | 144 | — | — | | — | — | — | — |
| Evaluation | Elastic | 1.5 | 1.5 | 2.0 | 2.3 | 2.1 | 1.6 | 1.6 | 1.8 | 2.3 |
| | modulus (GPa) | | | | | | | | | |
| | Tg (° C.) | 179 | 250 | 175 | 181 | 175 | 175 | 175 | 172 | 177 |
| | CTE (ppm/° C.) | 83 | 67 | 84 | 82 | 88 | 88 | 89 | 86 | 83 |
| | Td5 (° C.) | 405 | 408 | 410 | 415 | 404 | 410 | 414 | 408 | 409 |
| | Dk | B | B | A | B | B | B | B | B | B |
| | Df | A | A | A | A | A | A | A | A | A |
| | Toughness | A | A | A | A | B | A | A | A | A |

A: 10.0 mm or less
B: 10.1 mm or more and 15.0 mm or less
C: 15.1 mm or more

TABLE 5

| Example | | 10 | 11 | 12 | 13 | 14 |
|---|---|---|---|---|---|---|
| Component | A-15 | 100 | — | — | — | — |
| (A) | A-16 | — | 100 | — | — | — |
| | A-17 | — | — | 100 | — | — |
| | A-18 | — | — | — | 100 | — |
| | A-19 | — | — | — | — | 100 |
| Component | DCP | 0.42 | 0.45 | 0.43 | 0.43 | 0.47 |
| (B) | | | | | | |
| Organic | Toluene | — | — | — | — | — |
| solvent | DMF | — | — | — | — | |
| Evaluation | Elastic | 2.2 | 2.1 | 2.2 | 1.7 | 2.3 |
| | modulus | | | | | |
| | (GPa) | | | | | |
| | Tg (° C.) | 151 | 160 | 166 | 161 | 160 |
| | CTE | 90 | 88 | 89 | 92 | 89 |
| | (ppm/° C.) | | | | | |
| | Td5 (° C.) | 403 | 407 | 410 | 409 | 407 |
| | Dk | B | B | B | B | B |
| | Df | A | A | A | A | A |
| | Toughness | A | A | A | A | A |

TABLE 6

| Comparative Example | | 1 | 2 | 3 | 4 | 5 |
|---|---|---|---|---|---|---|
| Component | A-10 | 100 | — | — | — | — |
| (A) | A-11 | — | 100 | — | — | — |
| | A-12 | — | — | 100 | — | — |
| | A-13 | — | — | — | 100 | — |
| | A-14 | — | — | — | — | 100 |
| Component | DCP | 0.58 | 0.95 | 0.47 | 0.55 | 0.54 |
| (B) | | | | | | |
| Organic | Toluene | 11.50 | — | — | — | — |
| solvent | DMF | — | — | — | — | |
| Evaluation | Elastic | 1.6 | — | 2.2 | 1.0 | 0.4 |
| | modulus | | | | | |
| | (GPa) | | | | | |
| | Tg (° C.) | 109 | — | 136 | 66 | 39 |
| | CTE | 88 | — | 86 | 116 | 150 |
| | (ppm/° C.) | | | | | |
| | Td5 (° C.) | 403 | — | 401 | 403 | 402 |
| | Dk | B | — | B | A | A |
| | Df | A | — | A | A | A |
| | Toughness | B | — | C | A | A |

As is obvious from the results shown in Tables 4 and 5, it could be verified that the resin compositions that used the maleimide resins of Examples had, as the characteristics of cured products, excellent low dielectric characteristics (low Dk and low Df), high elastic modulus, high Tg, low CTE, and high toughness. Therefore, it can be expected to dramatically improve the characteristics of sealing materials for laminated plates such as printed substrates and electronic components such as semiconductors by using the maleimide resin of the present disclosure.

1. A maleimide resin obtained by reacting a tetracarboxylic acid dianhydride (a1), an amine (a2), and maleic anhydride (a3),
wherein the tetracarboxylic acid dianhydride (a1) includes a tetracarboxylic acid dianhydride having a fluorene skeleton, and
the amine (a2) include a dimer diamine and an amine having a biphenyl skeleton.

2. The maleimide resin according to claim 1, wherein the tetracarboxylic acid dianhydride having a fluorene skeleton contains at least one of 9,9-bis(3,4-dicarboxyphenyl) fluorene dianhydride and 9,9-bis[4-(3,4-dicarboxyphenoxy)phenyl]fluorene dianhydride.

3. The maleimide resin according to claim 1, wherein the amine having a biphenyl skeleton contains at least one of 4,4′-diamino-2,2′-dimethylbiphenyl, 4,4′-diamino-2,2′-diethylbiphenyl, 4,4′-diamino-3,3′-dimethylbiphenyl, 4,4′-diamino-3,3′-diethylbiphenyl, 4,4′-diamino-3,3′,5,5′-tetramethylbiphenyl, 4,4′-diamino-3,3′,5,5′-tetraethylbiphenyl, 4,4′-diamino-2,2′-bis(trifluoromethyl) biphenyl, 4,4′-diamino-2,2′-dimethoxybiphenyl, or 4,4′-diamino-3,3′-dimethoxybiphenyl.

4. The maleimide resin according to claim 1, wherein the dimer diamine contains at least one of a compound represented by the following general Formula (1) and a compound represented by the following general Formula (2): 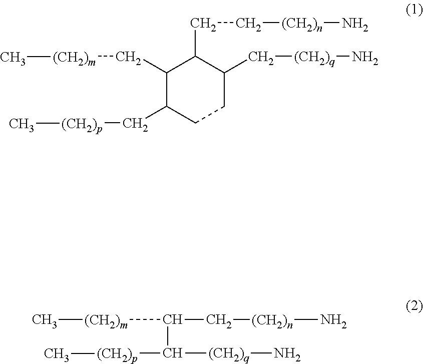
wherein in Formulas (1) and (2), m, n, p, and q each represent an integer of 1 or greater selected such that m+n=6 to 17 and p+q=8 to 19; and a bond indicated by a dashed line means a carbon-carbon single bond or a carbon-carbon double bond; provided that when the bond indicated by a dashed line is a carbon-carbon double bond, Formulas (1) and (2) have a structure in which the number of hydrogen atoms bonded to each of the carbon atoms constituting the carbon-carbon double bond is one less than the number shown in Formula (1) or (2).

5. The maleimide resin according to claim 1, wherein the maleimide resin has a weight average molecular weight of 3000 to 40000.

6. A resin composition comprising the maleimide resin according to claim 1.

7. The resin composition according to claim 6, further comprising a polymerization initiator.

8. A cured product of the resin composition according to claim 6.

9. A sheet comprising the resin composition according to claim 6 and a substrate.

10. The sheet according to claim 9, wherein the substrate is an organic substrate.

11. The sheet according to claim 9, wherein the substrate is an inorganic substrate.

12. A laminate obtained by further thermocompression bonding a substrate to an adhesive surface of the sheet according to claim 9.

13. A printed wiring board using the sheet according to claim 9.

14. A printed wiring board using the laminate according to claim 12.
